(19) United States
(12) Patent Application Publication
(10) Pub. No.: US 2026/0040714 A1
(43) Pub. Date: Feb. 5, 2026

(54) VERTICAL CHARGE TRANSFER IMAGING SENSOR AND MANUFACTURING METHOD THEREFOR

(71) Applicant: WUHAN XINXIN SEMICONDUCTOR MANUFACTURING CO., LTD., Wuhan, Hubei (CN)

(72) Inventors: Kaiwei CAO, Wuhan, Hubei (CN); Peng SUN, Wuhan, Hubei (CN)

(21) Appl. No.: 18/996,232

(22) PCT Filed: Oct. 13, 2023
(86) PCT No.: PCT/CN2023/124404

§ 371 Date: Jan. 17, 2025

(30) Foreign Application Priority Data
Nov. 23, 2022 (CN) 202211477404.0

(51) Int. Cl. H10F 39/00; H10F 39/18

(52) U.S. Cl. CPC H10F 39/812; H10F 39/014; H10F 39/18; H10F 39/802; H10F 39/80373; H10F 39/807

(57) ABSTRACT

A vertically charge transferring pixel sensor (VPS) and a method of manufacturing the VPS. In the VPS, shallow trench isolations (STIs) and deep trench isolations (DTIs) are formed at one side of the semiconductor substrate. Each DTI includes a deep trench extending through the semiconductor substrate and, filled in the deep trench, a trench electrode and a first isolation dielectric. The DTIs define a plurality of substrate cells in a pixel area. Each substrate cell includes a light sensing region and a charge readout region, which are isolated from each other by one STI. At least one substrate electrode is formed at the other side of the semiconductor substrate to contact the respective substrate cells and isolated from the trench electrodes. The DTIs provide physical pixel-to-pixel isolation. Moreover, the trench electrodes provide operable electrode terminals for the VPS, which entail a variety of modes of operation.

### TECHNICAL FIELD

The present invention relates to light sensing technology and, in particular, to a vertically charge transferring pixel sensor (VPS) and a method of manufacturing the VPS.

### BACKGROUND

A vertically charge transferring pixel sensor (VPS) is an image sensor that utilizes a semiconductor substrate and floating gate transistors to provide imaging capabilities. Referring to FIGS. 1 and 2, each VPS pixel includes a semiconductor substrate 10, the semiconductor substrate 10 has a light sensing region 11 and a charge readout region 12, which are isolated from each other by a shallow trench isolation (STI). On a front side of the semiconductor substrate 10 are formed a gate dielectric layer 13, a floating gate FG, an intergate dielectric layer 14 and a control gate CG, all extending from the light sensing region 11 to the charge readout region 12. A source regions S and a drain region D are formed in the charge readout region 12 on opposite sides of the control gate (CG). Thus, each pixel includes a MOS capacitor on the light sensing region 11 and a readout transistor formed in the charge readout region 12, which are connected to each other. During VPS operation, light is incident on the semiconductor substrate 10 from its backside, generating photoelectrons which then move toward the control gate CG under the action of an appropriate bias voltage and gather on a lower surface of the gate dielectric layer 13 above the light sensing region 11, or cross a potential barrier and enter the floating gate (FG). This causes the occurrence of a drain current change and/or a threshold voltage change to the readout transistor. Such changes can be detected and used for photoelectric sensing and imaging.

Compared with traditional photodiode-based semiconductor sensors (e.g., CMOS image sensors), VPS has higher full-well charge capacity at a given pixel size. Therefore, they can provide a higher signal-to-noise ratio and profound advantages in pixel miniaturization.

Currently, for VPS-based pixel miniaturization, how to ensure desirable photoelectric conversion efficiency while avoiding pixel-to-pixel crosstalk is most challenging.

### SUMMARY

The present invention provides a vertically charge transferring pixel sensor (VPS) with desirable photoelectric conversion efficiency and free of pixel-to-pixel crosstalk and a method of manufacturing such a VPS.

In one aspect, the present invention provides a VPS including:
a semiconductor substrate of a first doping type, which has a pixel area and a peripheral area;
shallow and deep trench isolations formed at a first side of the semiconductor substrate, each of the deep trench isolations including a deep trench extending through the semiconductor substrate and, filled in the deep trench, a trench electrode and a first isolation dielectric, the first isolation dielectric insulating the trench electrode from the semiconductor substrate, the deep trench isolations defining a plurality of substrate cells in the pixel area, each of the substrate cell including a light sensing region and a charge readout region, which are isolated from each other by one of the shallow trench isolations;
a gate dielectric layer, floating gates, an intergate dielectric layer and control gates, which are formed over surfaces of the respective substrate cells and extend from the light sensing regions to the charge readout regions, and source regions and drain regions formed on opposite sides of the respective control gates in the respective charge readout regions; and
at least one substrate electrode formed at a second side of the semiconductor substrate, the at least one substrate electrode contacts two adjacent substrate cells and is isolated from the corresponding trench electrode.

Optionally, the semiconductor substrate may also have a trench electrode pickup area peripheral to the pixel area, wherein the trench electrodes in the deep trenches extend from the pixel area to the trench electrode pickup area, and from the bottom to the top of the deep trenches in the trench electrode pickup area.

Optionally, the VPS may further include trench electrode connections formed in the trench electrode pickup area and covering the trench electrodes.

Optionally, in the pixel area, the first isolation dielectric filled in the deep trenches may include a linear oxide layer and a deep-trench filling layer, the linear oxide layer intervening between the trench electrodes and the semiconductor substrate, the deep-trench filling layer covering the trench electrodes and located at the top of the deep trenches.

Optionally, the at least one substrate electrode may be formed at the second side of the semiconductor substrate in correspondence with the deep trenches in the pixel area, wherein a second isolation dielectric intervenes between the at least one substrate electrode and the trench electrodes.

Optionally, the second isolation dielectric may include a high-k material.

Optionally, the control gates formed over the respective substrate cells may be connected to form a plurality of word lines, each word line running across a plurality of ones of the substrate cells.

In another aspect, the present invention provides a method of manufacturing a VPS, which includes:
providing a semiconductor substrate having a pixel area;
forming shallow trench isolations and deep trench isolations at a first side of the semiconductor substrate, each of the deep trench isolations including a deep trench extending through the semiconductor substrate and, filled in the deep trench, a trench electrode and a first isolation dielectric, the first isolation dielectric insulating the trench electrode from the semiconductor substrate, the deep trench isolations defining a plurality of substrate cells in the pixel area, each of the substrate cell including a light sensing region and a charge readout region, which are isolated from each other by one of the shallow trench isolations;
forming a gate dielectric layer, floating gates, an intergate dielectric layer and control gates over surfaces of the respective substrate cells, which extend from the light sensing regions to the charge readout regions, and forming source regions and drain regions on opposite sides of the respective control gates in the respective charge readout regions; and
thinning the semiconductor substrate from a second side thereof until the deep trench isolations are exposed and forming at least one substrate electrode at the second side, which contacts two adjacent substrate cells and is isolated from the corresponding trench electrode.

Optionally, forming the shallow trench isolations and the deep trench isolations formed at the first side of the semiconductor substrate may include:
forming a pad oxide layer and a first hard mask layer on a surface of the semiconductor substrate, and forming the shallow trench isolations which extend through the first hard mask layer, the pad oxide layer and part of the semiconductor substrate;
forming a second hard mask layer, which covers the first hard mask layer and the shallow trench isolations;
forming the deep trenches which extend through the second hard mask layer, the first hard mask layer, the pad oxide layer and part of the semiconductor substrate;
forming a linear oxide layer and a conductive layer in the deep trenches, the linear oxide layer covering the semiconductor substrate exposed in the deep trenches, the conductive layer covering the linear oxide layer and filling the deep trenches, wherein a top surface of the conductive layer is higher than the surface of the semiconductor substrate;
etching back the conductive layer in the pixel area until the top surface of the conductive layer is lowered under the surface of the semiconductor substrate, forming spaces on top of the deep trenches in the pixel area, with the remainder of the conductive layer forming the trench electrodes; and
forming a deep-trench filling layer in the spaces, wherein the linear oxide layer and the deep-trench filling layer make up the first isolation dielectric.

Optionally, the semiconductor substrate may also have a trench electrode pickup area peripheral to the pixel area, wherein the trench electrodes in the deep trenches extend from the pixel area to the trench electrode pickup area, and from the bottom to the top of the deep trenches in the trench electrode pickup area.

Optionally, forming the at least one substrate electrode may include:
forming first trenches at the deep trench isolations exposed at the second side of the semiconductor substrate, wherein the trench electrodes and the substrate cells around the trench electrodes are exposed in the first trenches;
forming a second isolation dielectric over the second side, which fills the first trenches and covers surfaces of the substrate cells;
forming second trenches, the bottom of which is located around the top of the first trenches, wherein the substrate cells around the deep trench isolations are exposed at side surfaces of the second trenches, and the trench electrodes are covered by the second isolation dielectric; and
filling a conductive material in the second trenches, forming the at least one substrate electrode.

The VPS and method of the present invention have the benefits as follows:

First, the deep trench isolations extend through the semiconductor substrate and define, in the pixel area, the plurality of substrate cells corresponding to respective VPS pixels. In this way, they provide physical pixel-to-pixel isolation, which can ensure good photoelectric conversion efficiency of the VPS and effectively avoid pixel-to-pixel crosstalk, facilitating pixel miniaturization.

Second, at least one substrate electrode is formed at the second side of the semiconductor substrate (i.e., the side away from the control gates), leaving a larger area for the control gates and additionally facilitating pixel miniaturization.

Third, the deep trench isolations include deep trenches extending through the semiconductor substrate, and filled in the deep trenches, the trench electrodes and the first isolation dielectric. The first isolation dielectric isolates the trench electrodes from the semiconductor substrate. The trench electrodes provide operable electrode terminals for the VPS, which can cooperate with other electrode terminals of the sensor to entail a variety of modes of operation.

Fourth, the trench electrodes can be coupled to the substrate electrodes and a positive bias voltage may be applied for light sensing between the substrate electrodes and the trench electrodes to increase a potential barrier at interfaces of the deep trench isolations and the substrate cells. This can reduce the probability of photoelectrons being captured at the interfaces, contributing to improved photoelectric conversion efficiency and helping mitigate the dark current and white pixel problems. Additionally, the positive bias voltage is flexibly adjustable, allowing the isolation dielectric between the trench electrodes and the substrate cells to be selected as a cheap low-k material.

Fifth, after a light sensing and charge readout cycle is completed, a negative bias voltage can be applied between the substrate electrodes and the trench electrodes to reset the sensor, releasing charge captured around boundaries of the deep trench isolations. This is helpful in reducing background noise for the next light sensing and charge readout cycle.

### BRIEF DESCRIPTION OF THE DRAWINGS

FIG. 1 is a schematic plan view of a VPS pixel.

FIG. 2 is a schematic cross-sectional view taken along line XX′ of FIG. 1.

FIG. 3 is a schematic plan view of a VPS according to an embodiment of the present invention.

FIG. 4 is a schematic cross-sectional view of part of FIG. 3 taken along line AA′.

FIG. 5 is a flowchart of a method of manufacturing a VPS according to an embodiment of the present invention.

FIGS. 6A to 6V are schematic cross-sectional views of structures resulting from steps in a method of manufacturing a VPS according to an embodiment of the present invention.

### DETAILED DESCRIPTION

Vertically charge transferring pixel sensors and methods of manufacturing the same according to specific embodiments of the present invention will be described in greater detail below with reference to the accompanying drawings. From the following description, advantages and features of the present invention will be more apparent. Note that the figures are provided in a very simplified form not necessarily drawn to exact scale for the only purpose of helping explain the disclosed embodiments in a more convenient and clearer way. Embodiments of the present invention should not be construed as limited to the particular shapes of regions illustrated herein but are to include deviations in shapes that result, for example, from manufacturing. For the sake of clarity, throughout the figures that help illustrate the embodiments disclosed herein, like elements are in principle labeled with like reference numbers, and repeated descriptions thereof are omitted.

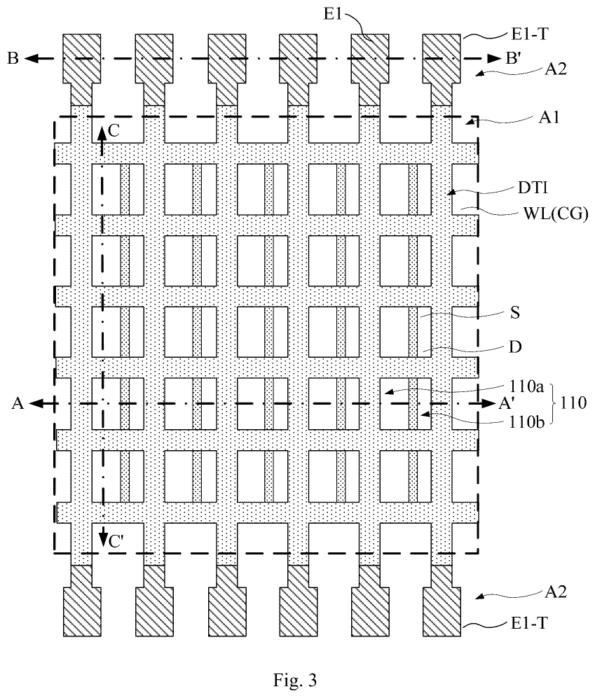

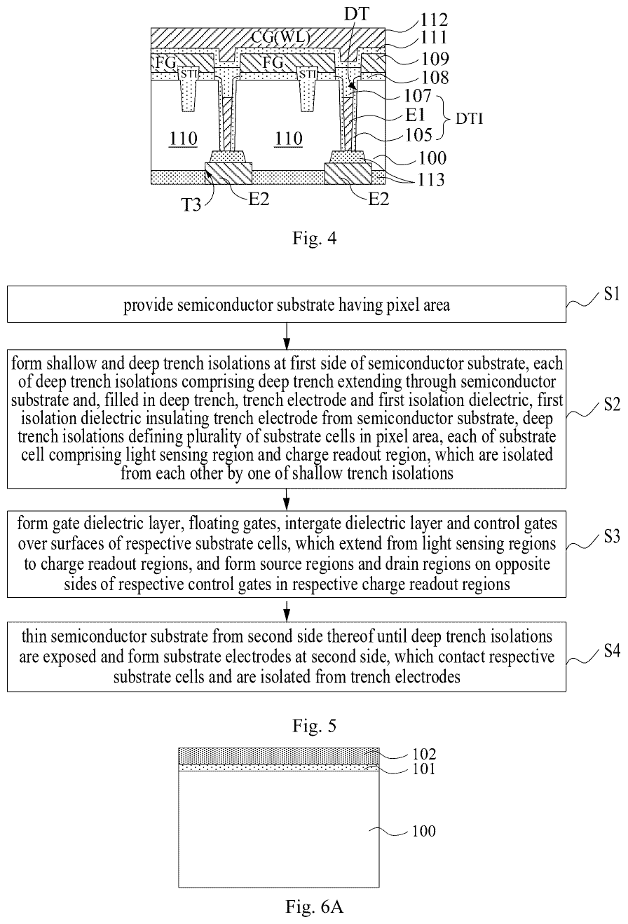

Referring to FIGS. 3 and 4, embodiments of the present invention include a vertically charge transferring pixel sensor (referred to hereinafter as “VPS sensor”) including:
a semiconductor substrate 100, the semiconductor substrate 100 has a pixel area A1;

shallow trench isolations STI and deep trench isolations DTI formed at one side of the semiconductor substrate 100, each deep trench isolation DTI including a deep trench DT extending through the semiconductor substrate 100 and, filled in the deep trench DT, a trench electrode E1 and a first isolation dielectric (in particular, for example, a linear oxide layer 105 and a deep-trench filling layer 107), the first isolation dielectric insulating the trench electrode E1 from the semiconductor substrate 100, the deep trench isolations DTI defining a plurality of substrate cells 110 in the pixel area A1, each substrate cell 110 including a light sensing region 110a and a charge readout region 110b, which are isolated from each other by one of the shallow trench isolations STI;
a gate dielectric layer 108, floating gates FG, an intergate dielectric layer 111 and control gates CG, which are formed over surfaces of the respective substrate cells 110 and extend from the light sensing regions 110a to the charge readout regions 110b, and source regions S and drain regions D formed on opposite sides of the respective control gates CG in the respective charge readout regions 110b; and
substrate electrodes E2 formed at the other side of the semiconductor substrate 100, the substrate electrodes E2 contact the respective substrate cells 110 and are isolated from the trench electrodes E1.

The semiconductor substrate 100 may be any of various suitable semiconductor substrates known in the art, and may be made of a material including silicon, germanium, silicon germanium, silicon carbide, gallium arsenide, gallium phosphide, indium phosphide, indium arsenide, indium antimonide or the like. For example, the semiconductor substrate 100 may be doped with ions. In particular examples, it may be a silicon substrate doped with boron or boron difluoride. In the former case, the doped boron ions may be present at a density of, for example, 1×10¹²/cm² to 2×10¹²/cm² (p−). In the charge readout regions 110b of the semiconductor substrate 100, p-body regions (PW, not shown) may be formed, and the source regions S and the drain regions D may be, for example, n-doped areas formed on top of the p-body regions. It is to be noted that although the floating gate transistors in the VPS pixels are described herein primarily as n-type devices, as an example, it will be understood that the floating gate transistors may also be p-type devices, and in this case, the n-body regions are formed in the charge readout regions 110b, and the source regions S and the drain regions D are p-doped areas.

Optionally, the plurality of substrate cells 110 in the pixel area A1 may be arranged into an array, the plurality of substrate cells 110 each correspond to one pixel including a MOS capacitor formed on the light sensing region 110a and a readout transistor formed in the charge readout region 110b, of the substrate cell 110.

As shown in FIG. 3, in this embodiment, the semiconductor substrate 100 further includes a peripheral area peripheral to the pixel area A1, in which some circuits for the VPS may be formed. However, the present invention is not so limited, as in some embodiments, the peripheral area may be provided by another substrate, which may be stacked and connected with the semiconductor substrate 100.

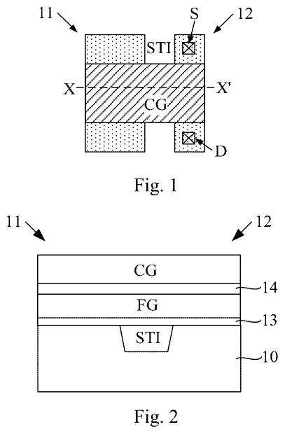

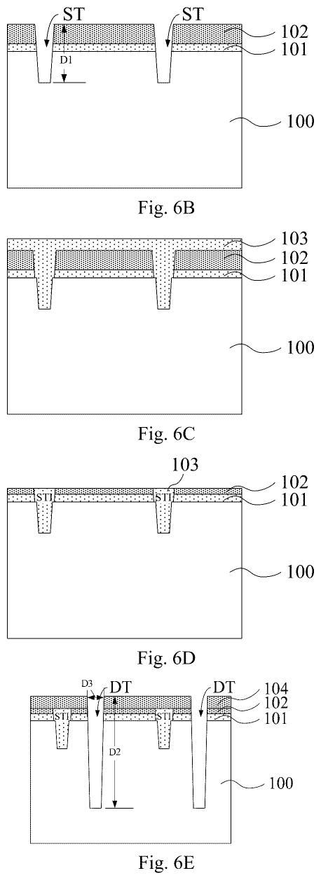

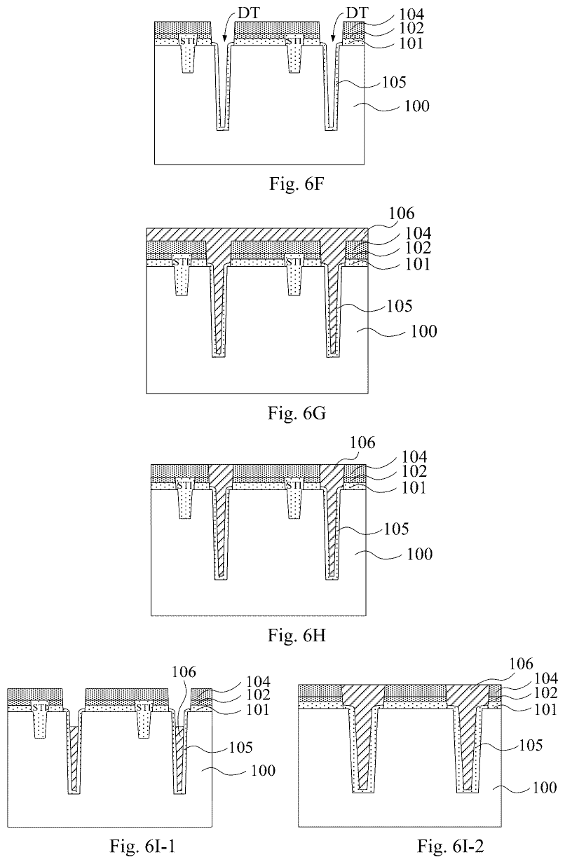

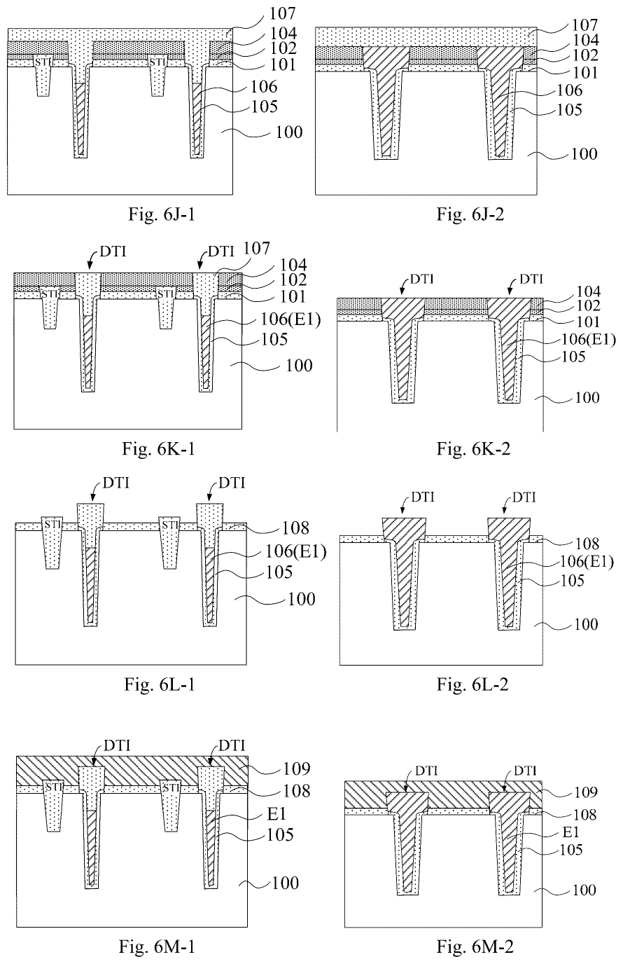

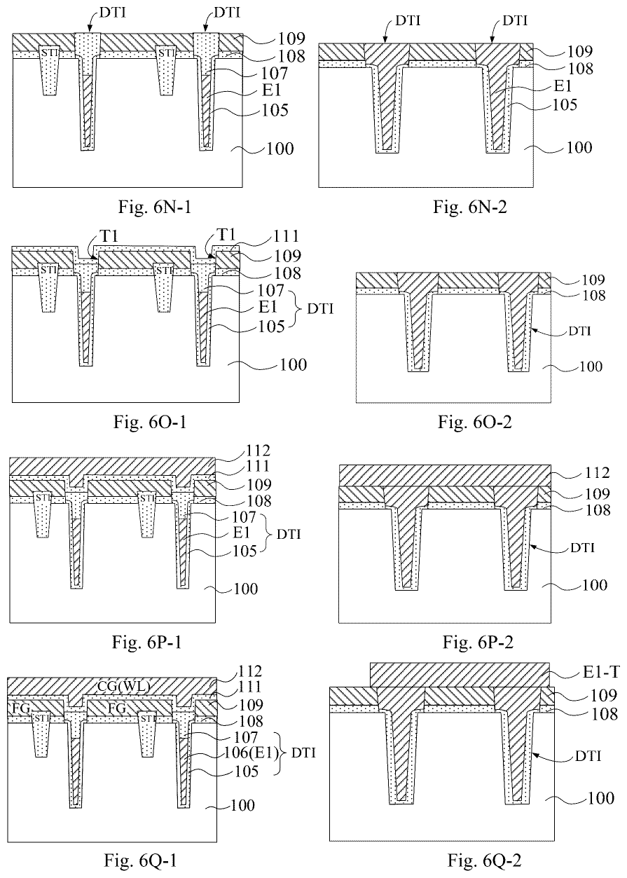

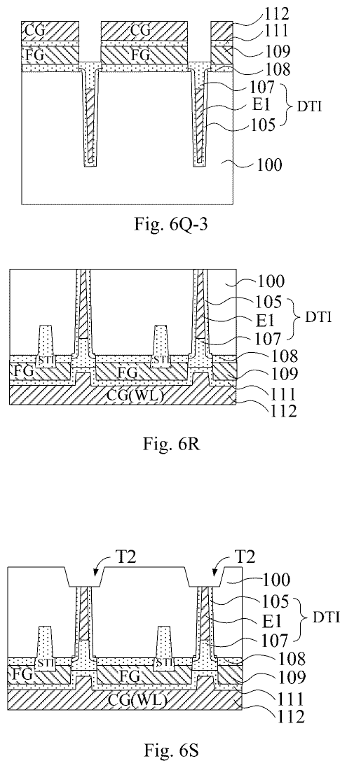

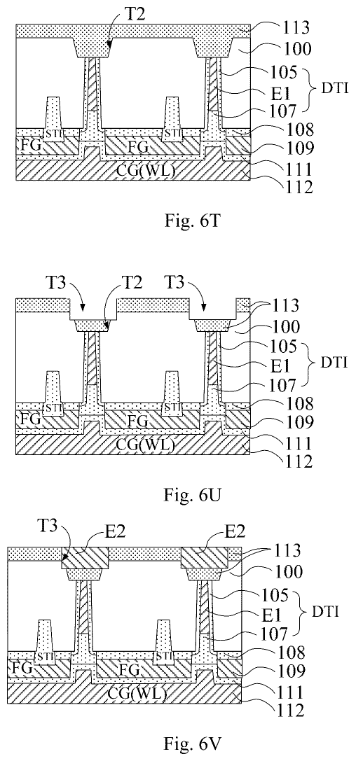

In this embodiment, part of the peripheral area is used as a trench electrode pickup area A2, where connections are formed with the trench electrodes E1. The deep trenches DT and trench electrodes E1 therein extend from the pixel area A1 to the trench electrode pickup area A2. In the pixel area A1, trench electrodes E1 underlie a lower surface of the gate dielectric layer 108 and are covered by the deep-trench filling layer 107. In the trench electrode pickup area A2, the trench electrodes E1 extend from the bottom to the top of the deep trenches DT and optionally protrude beyond a surface of the semiconductor substrate 100 (see FIG. 6Q-2). Optionally, the VPS may further include trench electrode connections E1-T, the trench electrode connections E1-T are formed in the trench electrode pickup area A2 so as to cover the trench electrodes E1, the trench electrode connections E1-T are electrically connected to the trench electrodes E1.

In some embodiments, the substrate electrodes E2 may be formed at the other side of the semiconductor substrate 100 in correspondence with the deep trenches DT in the pixel area A1, and a second isolation dielectric 113 may be provided between the substrate electrodes E2 and the trench electrodes E1.

In some embodiments, the second isolation dielectric 113 may include a high-k material (with a dielectric constant greater than 3.9). Optionally, the second isolation dielectric 113 may further cover end faces of the semiconductor substrate 100 at the other side.

In some embodiments, the control gates CG above the respective substrate cells 110 may be connected to form a plurality of word lines WL, each of the word lines WL runs across several ones of the substrate cells 110.

Thus, each VPS pixel includes: a substrate cell 110; a gate dielectric layer 108, a floating gate FG, an intergate dielectric layer 111 and a control gate CG, all formed on the substrate cell 110; and a source region S and a drain region D formed in a charge readout region 110b on opposite sides of the control gate CG. The light sensing region 110a and the gate dielectric layer 108, floating gate FG, intergate dielectric layer 111 and control gate CG thereon form a MOS capacitor for light sensing, and the source region S and drain region D in the charge readout region 110b and the gate dielectric layer 108, floating gate FG, intergate dielectric layer 111 and control gate CG on the charge readout region 110b form a readout transistor for charge readout.

As an example, the VPS may perform the following process to achieve light sensing and readout.

At first, a light sensing operation is carried out. A negative bias voltage (e.g., −3 V) is applied to the semiconductor substrate 100, and a positive bias voltage to the control gates CG, forming a continuous depleted region in the semiconductor substrate 100. When photons enter the depleted region from the side of the semiconductor substrate 100 away from the control gate CG, they are excited into photoelectrons, which are then driven by the electric field to gather on the lower surface of the gate dielectric layer 108 above the light sensing region 110a, or cross a potential barrier and enter the floating gate FG. As the floating gate FG above the light sensing region 110a and the charge readout region 110b are continuous, changes occur in the floating gate FG above the charge readout region 110b, which in turn cause a drain current change and/or a threshold voltage change in the readout transistor.

A charge readout operation follows, in which the source region S and the semiconductor substrate 100 are grounded (0 V) and a positive bias voltage (e.g., higher than 0 and lower than 3 V) is applied to the drain region D, allowing detection of the drain current change or threshold voltage change in the readout transistor.

A reset operation is then carried out, in which a negative bias voltage is applied to the control gate CG and a positive bias voltage (e.g., higher than 0 and lower than 3 V) to the semiconductor substrate 100 and the source region S, releasing the photoelectrons on the lower surface of the gate dielectric layer 108 or in the floating gate FG.

According to embodiments of the present invention, the trench electrodes E1 provide operable electrode terminals for the VPS, which can cooperate with other electrode terminals of the sensor (e.g., electrode terminals individually connected to the control gates, source regions and drain regions and the substrate electrodes) to entail a variety of modes of operation. In some embodiments, the trench electrodes E1 may serve as coupling terminals for the substrate electrodes E2 and a positive bias voltage may be applied between the substrate electrodes E2 and the trench electrodes E1 to increase a potential barrier at interfaces of the deep trench isolations DTI and the substrate cells 110. This can reduce the probability of photoelectrons being captured at the interfaces, contributing to improved photoelectric conversion efficiency and helping mitigate the dark current and white pixel problems. In addition, following a light sensing and charge readout cycle, a negative bias voltage may be applied between the substrate electrodes and the trench electrodes to reset the sensor, releasing charge captured around boundaries of the deep trench isolations. This is helpful in reducing background noise for the next light sensing and charge readout operations.

Embodiments of the present invention also include a method, according to which the above-discussed VPS is obtainable. The method is described below with reference to FIGS. 5 and 6A to 6V.

FIG. 6A is a schematic cross-sectional view of a structure resulting from forming a pad oxide layer and a first hard mask layer on a semiconductor substrate. The cross-sectional view of FIG. 6A is, for example, taken along line AA′ in the plan view of FIG. 3. Referring to FIGS. 3 and 5 (step S1) and to FIG. 6A, a semiconductor substrate 100 of a first doping type is provided, the semiconductor substrate 100 has a pixel area A1. The semiconductor substrate 100 is, for example, a p-doped (p−) silicon substrate. Light sensing pixels are to be formed in the pixel area A1. The semiconductor substrate 100 may include a trench electrode pickup area A2 peripheral to the pixel area A1.

Referring to FIG. 5, in step S2, shallow trench isolations STI and deep trench isolations DTI are then formed at one side of the semiconductor substrate 100. In particular, this may be accomplished by performing the process as follows.

As shown in FIG. 6A, a pad oxide layer 101 and a first hard mask layer 102 are formed on a surface of the semiconductor substrate 100. For example, the pad oxide layer 101 includes silicon oxide of a given thickness. For example, the first hard mask layer 102 includes silicon nitride of a given thickness.

FIG. 6B is a schematic cross-sectional view of a structure resulting from forming shallow trenches in the semiconductor substrate. As shown in FIG. 6B, locations where the shallow trench isolations STI are to be formed may be defined using a photolithography process. One or more etching processes may be then carried out to form shallow trenches ST, which extends through the first hard mask layer 102, the pad oxide layer 101 and part of the semiconductor substrate 100. The shallow trenches ST may have a depth D1 of about 100 nm to 400 nm, such as about 200 nm.

FIG. 6C is a schematic cross-sectional view of a structure resulting from forming a shallow-trench filling layer. As shown in FIG. 6C, an oxide layer (not shown) is formed on inner surfaces of the shallow trenches ST and a shallow-trench filling layer 103 is then deposited. The shallow-trench filling layer 103 fills the shallow trenches ST and is deposited to a thickness above the first hard mask layer 102. The shallow-trench filling layer 103 may include silicon oxide or another isolation dielectric. Optionally, before the oxide layer is formed on the inner surfaces of the shallow trenches ST, the portions of the shallow trenches ST formed in the first hard mask layer 102 and the pad oxide layer 101 may be widened, in order to reduce the risk of electrical leakage in active areas of the semiconductor substrate 100 subsequently defined by the shallow trenches ST as a result of removing the first hard mask layer 102 and the pad oxide layer 101.

FIG. 6D is a schematic cross-sectional view of a structure resulting from planarizing the shallow-trench filling layer. As shown in FIG. 6D, the shallow-trench filling layer 103 is planarized (e.g., by chemical mechanical polishing (CMP)), exposing a top surface of the first hard mask layer 102. The remainder of the shallow-trench filling layer 103 fills the shallow trenches ST and forms the shallow trench isolations STI.

FIG. 6E is a schematic cross-sectional view of a structure resulting from forming a second hard mask layer. As shown in FIG. 6E, a second hard mask layer 104 (e.g., silicon nitride) is formed, the second hard mask layer 104 covers the shallow trench isolations STI and the first hard mask layer 102. An aggregate thickness of the first hard mask layer 102 and the second hard mask layer 104 is about 2000 Å. After that, a photolithography process is performed to define locations where the deep trench isolations DTI are to be formed. One or more etching processes are then carried out to form deep trenches DT extending through the second hard mask layer 104, the first hard mask layer 102, the pad oxide layer 101 and part of the semiconductor substrate 100. The deep trenches DT have a depth D2 greater than the depth D1 of the aforementioned shallow trenches ST. For example, the depth D2 of the deep trenches DT may range from 1.5 μm to 2.5 μm. Further, the depth D2 may exceed 1.8 μm, such as about 2 μm. The deep trenches DT may have an opening width D3 of, for example, about 80 nm.

The cross-sectional view of FIG. 6E may be, for example, taken along line AA′ in the plan view of FIG. 3. Referring to FIGS. 3 and 6E, portions of the deep trenches DT are formed in the pixel area A1 of the semiconductor substrate 100 to partition the pixel area A1 into a plurality of substrate cells 110. Portions of the shallow trench isolations STI are formed in the respective substrate cells 110. Each substrate cell 110 includes a light sensing region 110a and a charge readout region 110b, which are isolated from each other by the shallow trench isolations STI. The deep trenches DT extend from the pixel area A1 into the trench electrode pickup area A2. As shown in FIG. 3, for example, the deep trenches DT in the trench electrode pickup area A2 may have a width greater than that of the deep trenches DT in the pixel area A1. There may be one or more trench electrode pickup areas A2 on respective sides of the pixel area A1.

FIG. 6F is a schematic cross-sectional view of a structure resulting from forming a linear oxide layer. As shown in FIG. 6F, a linear oxide layer 105 is formed on inner surfaces of the deep trenches DT, the linear oxide layer 105 covers the semiconductor substrate 100 exposed in the deep trenches DT. Before this, the portions of the deep trenches DT in the second hard mask layer 104, the first hard mask layer 102 and the pad oxide layer 101 may be widened. Subsequently, an annealing process may be carried out to repair lattice defects in the semiconductor substrate 100 possibly introduced by the formation of the deep trenches DT. The annealing process may be performed, for example, at a temperature of about 1100° C.

FIG. 6G is a schematic cross-sectional view of a structure resulting from forming a conductive layer. As shown in FIG. 6G, a conductive material is deposited in the deep trenches DT and on the second hard mask layer 104, forming a conductive layer 106. The conductive layer 106 fills the deep trenches DT and is deposited to a thickness above the second hard mask layer 104. The conductive layer 106 may be formed of a conductive material with good light shielding properties. Optionally, the conductive layer 106 may include one of tungsten, tungsten silicide, titanium, titanium nitride and doped polysilicon, or a combination of two or more thereof. In this embodiment, the conductive layer 106 may be doped polysilicon, for example. After the deposition is completed, the doped polysilicon may be annealed and recrystallized to an appropriate grain size.

FIG. 6H is a schematic cross-sectional view of a structure resulting from planarizing the conductive layer. As shown in FIG. 6H, the conductive layer 106 is planarized (e.g., by CMP), exposing a top surface of the second hard mask layer 104. The remainder of the conductive layer 106 fills the deep trenches DT.

Next, an etch back process is carried out on the conductive layer 106 in the pixel area A1, which proceeds to a depth below the surface of the semiconductor substrate 100, forming spaces on top of the deep trenches DT in the pixel area A1. FIGS. 61-1 and 61-2 are schematic cross-sectional views respectively of the pixel area and the trench electrode pickup area of a structure resulting from etching back the conductive layer. Specifically, FIG. 6I-1 is, for example, taken along line AA′ in the plan view of FIG. 3, and FIG. 6I-2 is, for example, taken along line BB′ in the plan view of FIG. 3. As shown in FIG. 6I-1, as a result of the conductive layer 106 in the pixel area A1 being etched back, the conductive layer 106 in the pixel area A1 is locally thinned and the deep trenches DT in the pixel area A1 are partially voided, forming spaces. After the etch back process is completed, a top surface of the trench conductive layer 106 in the pixel area A1 is locally lower than the top surface of the semiconductor substrate 100. As shown in FIG. 6I-2, in the trench electrode pickup area A2, the conductive layer 106 still extends to top edges of the deep trenches DT. The remainder of the trench conductive layer 106 forms trench electrodes E1.

FIGS. 6J-1 and 6J-2 are schematic cross-sectional views respectively of the pixel area and the trench electrode pickup area of a structure resulting from forming a deep-trench filling layer. As shown in FIGS. 6J-1 and 6J-2, a deep-trench filling layer 107 is deposited, the deep-trench filling layer 107 covers the trench conductive layer 106 in the pixel area A1 and the trench electrode pickup area A2 and is deposited to a thickness above the second hard mask layer 104. The deep-trench filling layer 107 may include silicon oxide or another isolation dielectric. Here, the linear oxide layer 105 and the deep-trench filling layer 107 are collectively referred to as a first isolation dielectric. The trench electrodes E1 are buried in the first isolation dielectric and insulated from the semiconductor substrate 100.

FIGS. 6K-1 and 6K-2 are schematic cross-sectional views respectively of the pixel area and the trench electrode pickup area of a structure resulting from planarizing the deep-trench filling layer. As shown in FIGS. 6K-1 and 6K-2, the deep-trench filling layer 107 is planarized (e.g., by CMP), exposing the top surface of the second hard mask layer 104. As a result of the above steps, the deep trench isolations DTI are formed in the semiconductor substrate 100 as to be embedded therein at one side of the semiconductor substrate 100. In the pixel area A1, the deep trench isolations DTI include, filled in the deep trenches DT, the linear oxide layer 105, part of the trench electrodes E1 and the deep-trench filling layer 107. In the trench electrode pickup area A2, the deep trench isolations DTI include, filled in the deep trenches DT, the linear oxide layer 105 and part of the trench electrodes E1. The trench electrodes E1 extend from the pixel area A1 to the trench electrode pickup area A2.

Referring to FIG. 5, in step S3, on a surface of each substrate cell 110 are formed a gate dielectric layer, a floating gate FG, an intergate dielectric layer and a control gate CG, each extending from the light sensing region 110a to the charge readout region 110b. Moreover, in the charge readout region 110b, source and drain regions are formed on opposite sides of the control gate CG. A more detailed description of this is set forth below.

FIGS. 6L-1 and 6L-2 are schematic cross-sectional views respectively of the pixel area and the trench electrode pickup area of a structure resulting from removing the hard mask layers. As shown in FIGS. 6L-1 and 6L-2, the second hard mask layer 104 and the first hard mask layer 102 are removed. As a result, the deep trench isolations DTI protrude beyond the surface of the semiconductor substrate 100 to a level higher than the shallow trench isolations STI. The deep trench isolations DTI in the pixel area A1 surround the individual substrate cells 110. After that, an ion implantation process may be carried out to form body regions (not shown) in the charge readout regions 110b. For example, p-type ions may be implanted in the ion implantation process. Afterwards, the pad oxide layer 101 is removed, and a gate dielectric layer 108 is then formed on the surface of the semiconductor substrate 100.

FIGS. 6M-1 and 6M-2 are schematic cross-sectional views respectively of the pixel area and the trench electrode pickup area of a structure resulting from forming a floating-gate material layer. As shown in FIGS. 6M-1 and 6M-2, polysilicon is deposited to form a floating-gate material layer 109, the floating-gate material layer 109 fills gaps between the shallow trench isolations STI and the deep trench isolations DTI and is deposited to a thickness above the deep trench isolations DTI.

FIGS. 6N-1 and 6N-2 are schematic cross-sectional views respectively of the pixel area and the trench electrode pickup area of a structure resulting from planarizing the floating-gate material layer. As shown in FIGS. 6N-1 and 6N-2, the floating-gate material layer 109 is planarized, exposing the deep-trench filling layer 107 in the pixel area A1 and the trench electrodes E1 in the trench electrode pickup area A2. The remainder of the floating-gate material layer 109 is partitioned by the deep trench isolations DTI.

FIGS. 6O-1 and 6O-2 are schematic cross-sectional views respectively of the pixel area and the trench electrode pickup area of a structure resulting from forming an intergate dielectric layer. As shown in FIGS. 6O-1 and 6O-2, the deep-trench filling layer 107 is thinned using an etch back process so that top surfaces of the deep trench isolations DTI in the pixel area A1 are lowered (but are still not lower than the surface of the semiconductor substrate 100), forming grooves T1 between the substrate cells 110. An intergate dielectric layer 111 is then conformally formed over the semiconductor substrate 100, and the intergate dielectric layer 111 in the trench electrode pickup area A2 is then removed, exposing the underlying floating-gate material layer 109. For example, the intergate dielectric layer 111 may be an oxide-nitride-oxide (ONO) stack consisting of a lower silicon oxide layer, a silicon nitride layer and an upper silicon oxide layer.

FIGS. 6P-1 and 6P-2 are schematic cross-sectional views respectively of the pixel area and the trench electrode pickup area of a structure resulting from forming a control-gate material layer. As shown in FIGS. 6P-1 and 6P-2, doped polysilicon is deposited over the semiconductor substrate 100, forming a control-gate material layer 112. The floating-gate material layer 109 in the trench electrode pickup area A2 may be either retained or removed before the control-gate material layer 112 is formed.

FIGS. 6Q-1 and 6Q-3 are schematic cross-sectional views of the pixel area of a structure resulting from forming control gates and floating gates. For example, FIG. 6Q-1 is taken along line AA′ in the plan view of FIG. 3. For example, FIG. 6Q-3 is taken along line CC′ in the plan view of FIG. 3. FIG. 6Q-2 is a schematic cross-sectional view of the trench electrode pickup area of a structure resulting from forming trench electrode connections. For example, FIG. 6Q-2 is taken along line BB′ in the plan view of FIG. 3. As shown in FIGS. 3, 6Q-1, 6Q-2 and 6Q-3, a photolithography process and one or more etching processes are carried out to form floating gates FG and control gates CG over the individual substrate cells 110 and to etch the control-gate material layer 112 in the trench electrode pickup area A2 to form trench electrode connections E1-T in the trench electrode pickup area A2.

In particular, an anisotropic etching process may be performed to sequentially etch through the control-gate material layer 112, the intergate dielectric layer 111 and the floating-gate material layer 109 in the pixel area A1. The remainder of the control-gate material layer 112 forms a plurality of word lines (WL) in the pixel area A1, each of which runs over two or more of the substrate cells 110 and a deep trench isolations DTI between them. The word lines serve as the control gates CG, which reside above the floating gates FG and spaced apart therefrom by the intergate dielectric layer 111.

The trench electrode connections E1-T are formed in the trench electrode pickup area A2 so as to be connected to the trench electrodes E1, the trench electrode connections E1-T are isolated from the control gates CG in the pixel area A1. Through the trench electrode connections E1-T, a voltage can be applied to the trench electrodes E1. It is to be noted that, although the deep trenches DT in the pixel area A1 have been shown in FIG. 3 as laterally extending to trench electrode pickup areas A2 at both ends, the present invention is not so limited. As the deep trenches DT in the pixel area A1 can be brought into communication, in some embodiments, the lateral extension of the deep trenches DT to peripheral area(s) A2 may be configured as required. For example, the deep trenches DT in the pixel area A1 may each have only one end extending to a trench electrode pickup area A2.

Referring to FIG. 3, for example, in the substrate cells 110, the control gates CG may have a greater width over the light sensing regions 110a than over the charge readout regions 110b. An etching process is carried out to expose portions of the gate dielectric layer 108 on opposite sides of the control gates CG over the charge readout region 110b. Further, the exposed portions of the gate dielectric layer 108 may be stripped away, and spacers are formed on side walls of the gate dielectric layer 108, floating gates FG, intergate dielectric layer 111 and control gates CG. Ions are then implanted to the charge readout regions 110b exposed on opposite sides of the control gates CG, forming source regions S and drain regions D.

Referring to FIG. 5, in step S4, the semiconductor substrate 100 is thinned from the other side until the deep trench isolations DTI are exposed, and substrate electrodes E2 are formed on the other side so as to contact the respective substrate cells 110 and be isolated from the trench electrodes E1. Through the substrate electrodes E2, a voltage can be applied to the substrate cells 110.

FIG. 6R is a schematic cross-sectional view of a structure resulting from thinning the semiconductor substrate from the other side thereof. For example, FIG. 6R is taken along line AA′ in the plan view of FIG. 3. As shown in FIG. 6R, the semiconductor substrate 100 is thinned from the side away from the control gates CG, exposing the deep trench isolations DTI. More precisely, for example, the trench electrodes E1 in the deep trenches DT may be exposed, the trench electrodes E1 may be partially removed in the process of thinning. As a result, the deep trench isolations DTI in the pixel area A1 extend through the semiconductor substrate 100 and thereby providing complete physical isolation between the substrate cells 110.

As shown in FIG. 6S, photolithography and etching processes are performed on a surface of the thinned semiconductor substrate 100, forming first trenches T2 at the exposed deep trench isolations DTI. The trench electrodes E1 and the substrate cells 110 around the trench electrodes are exposed at inner surfaces of the first trenches T2. For example, the first trenches T2 may have inverted trapezoidal cross-sections.

As shown in FIG. 6T, a dielectric material is deposited in the first trenches T2 and surfaces of the substrate cells 110, forming a second isolation dielectric 113. Thus, the second isolation dielectric 113 fills the first trenches T2 and covers the surfaces of the substrate cells 110.

As shown in FIG. 6U, photolithography and etching processes are performed to form second trenches T3 in alignment with the first trenches T2. Bottom surfaces of the second trenches T3 are located around top edges of the first trenches T2, and the substrate cells 110 around the deep trench isolations DTI are exposed at side surfaces of the second trenches T3. The second isolation dielectric 113 that covers the trench electrodes E1 is exposed at the bottom surfaces of the second trenches T3. Additionally, the substrate cells 110 around the deep trench isolations DTI may also be exposed at the bottom surfaces of the second trenches T3.

The second isolation dielectric 113 may be a high-k material (with a dielectric constant k greater than 3.9), which can increase a potential barrier at interfaces of the first trenches T2 and the semiconductor substrate 100 (interface passivation). This can reduce the probability of photoelectrons being captured at the interfaces, contributing to improved photoelectric conversion efficiency. The high-k material may include A1₂O₃, Ta₂Os, ZrO₂, LaO, BaZrO, AlO, HfZrO, HfZION, HfLaO, HfSiON, HfSiO, LaSiO, AlSiO, HfTaO, HfTiO, (Ba,Sr) TiO₃(BST), TiO₂ or the like.

As shown in FIG. 6V, a conductive material is filled in the second trenches T3, forming substrate electrodes E2. The substrate electrodes E2 may include one of titanium, titanium nitride, tantalum nitride, aluminum, a copper alloy and an aluminum alloy, or a combination thereof.

The VPS and method of the present invention offer the benefits as follows: the deep trench isolations DTI formed at one side of the semiconductor substrate 100 provide physical pixel-to-pixel isolation, which can ensure good photoelectric conversion efficiency of the VPS and effectively avoid pixel-to-pixel crosstalk, facilitating pixel miniaturization. The substrate electrodes E2 are formed at the other side of the semiconductor substrate 100 (i.e., the side away from the control gates CG), leaving a larger area for the control gates CG and additionally facilitating pixel miniaturization. The trench electrodes E1 in the deep trench isolations DTI provide operable electrode terminals for the VPS, which can cooperate with other electrode terminals of the sensor (e.g., electrode terminals individually connected to the control gates, source regions and drain regions and the substrate electrodes) to entail a variety of modes of operation. For example, the trench electrodes E1 may be coupled to the substrate electrodes E2, and a positive bias voltage may be applied for light sensing between the substrate electrodes E2 and the trench electrodes E1 to increase a potential barrier at interfaces of the deep trench isolations and the substrate cells. This can reduce the probability of photoelectrons being captured at the interfaces, contributing to improved photoelectric conversion efficiency and helping mitigate the dark current and white pixel problems. Additionally, the positive bias voltage is flexibly adjustable, allowing the isolation dielectric between the trench electrodes and the substrate cells to be selected as a cheap low-k material (with a dielectric constant less than or equal to 3.9). As another example, after a light sensing and charge readout cycle is completed, a negative bias voltage may be applied between the substrate electrodes and the trench electrodes to reset the sensor, releasing charge captured around boundaries of the deep trench isolations. This is helpful in reducing background noise for the next light sensing and charge readout cycle.

It is to be noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A vertically charge transferring pixel sensor, comprising:
a semiconductor substrate having a pixel area;
shallow trench isolations and deep trench isolations formed at a first side of the semiconductor substrate, each of the deep trench isolations comprising a deep trench extending through the semiconductor substrate and, filled in the deep trench, a trench electrode and a first isolation dielectric, the first isolation dielectric insulating the trench electrode from the semiconductor substrate, the deep trench isolations defining a plurality of substrate cells in the pixel area, each of the substrate cell comprising a light sensing region and a charge readout region, which are isolated from each other by one of the shallow trench isolations;
floating gates, an intergate dielectric layer and control gates, which are formed over surfaces of the respective substrate cells and extend from the light sensing regions to the charge readout regions, and source regions and drain regions formed on opposite sides of the respective control gates in the respective charge readout regions; and
at least one substrate electrode formed at a second side of the semiconductor substrate, the at least one substrate electrode contacts two adjacent substrate cells and is isolated from the corresponding trench electrode that disposed between the two adjacent substrate cells.

2. The vertically charge transferring pixel sensor of claim 1, wherein the semiconductor substrate also has a trench electrode pickup area peripheral to the pixel area, wherein the trench electrodes in the deep trenches extend from the pixel area to the trench electrode pickup area, and from the bottom to the top of the deep trenches in the trench electrode pickup area.

3. The vertically charge transferring pixel sensor of claim 2, further comprising:
trench electrode connections formed in the trench electrode pickup area and covering the trench electrodes.

4. The vertically charge transferring pixel sensor of claim 1, wherein in the pixel area, the first isolation dielectric filled in the deep trenches comprises a linear oxide layer and a deep-trench filling layer, the linear oxide layer intervening between the trench electrodes and the semiconductor substrate, the deep-trench filling layer covering the trench electrodes and located at the top of the deep trenches.

5. The vertically charge transferring pixel sensor of claim 1, wherein the at least one substrate electrode is formed at the second side of the semiconductor substrate in correspondence with the deep trenches in the pixel area, wherein a second isolation dielectric intervenes between the at least one substrate electrode and the trench electrodes.

6. The vertically charge transferring pixel sensor of claim 5, wherein the second isolation dielectric comprises a high dielectric constant material.

7. The vertically charge transferring pixel sensor of claim 1, wherein the control gates formed over the respective substrate cells are connected to form a plurality of word lines, each word line running across a plurality of ones of the substrate cells.

8. A method of manufacturing a vertically charge transferring pixel sensor, comprising:
providing a semiconductor substrate having a pixel area;
forming shallow trench isolations and deep trench isolations at a first side of the semiconductor substrate, each of the deep trench isolations comprising a deep trench extending through the semiconductor substrate and, filled in the deep trench, a trench electrode and a first isolation dielectric, the first isolation dielectric insulating the trench electrode from the semiconductor substrate, the deep trench isolations defining a plurality of substrate cells in the pixel area, each of the substrate cell comprising a light sensing region and a charge readout region, which are isolated from each other by one of the shallow trench isolations;
forming floating gates, an intergate dielectric layer and control gates over surfaces of the respective substrate cells, which extend from the light sensing regions to the charge readout regions, and forming source regions and drain regions on opposite sides of the respective control gates in the respective charge readout regions; and
thinning the semiconductor substrate from a second side thereof until the deep trench isolations are exposed and forming at least one substrate electrode at the second side, which contacts two adjacent substrate cells and is isolated from the corresponding trench electrode that disposed between the two adjacent substrate cells.

9. The method of claim 8, wherein forming the shallow trench isolations and the deep trench isolations formed at the first side of the semiconductor substrate comprises:
forming a pad oxide layer and a first hard mask layer on a surface of the semiconductor substrate, and forming the shallow trench isolations which extend through the first hard mask layer, the pad oxide layer and part of the semiconductor substrate;
forming a second hard mask layer, which covers the first hard mask layer and the shallow trench isolations;
forming the deep trenches which extend through the second hard mask layer, the first hard mask layer, the pad oxide layer and part of the semiconductor substrate;
forming a linear oxide layer and a conductive layer in the deep trenches, the linear oxide layer covering the semiconductor substrate exposed in the deep trenches, the conductive layer covering the linear oxide layer and filling the deep trenches, wherein a top surface of the conductive layer is higher than the surface of the semiconductor substrate;
etching back the conductive layer in the pixel area until the top surface of the conductive layer is lowered under the surface of the semiconductor substrate, forming spaces on top of the deep trenches in the pixel area, with the remainder of the conductive layer forming the trench electrodes; and
forming a deep-trench filling layer in the spaces, wherein the linear oxide layer and the deep-trench filling layer make up the first isolation dielectric.

10. The method of claim 8, wherein the semiconductor substrate also has a trench electrode pickup area peripheral to the pixel area, wherein the trench electrodes in the deep trenches extend from the pixel area to the trench electrode pickup area, and from the bottom to the top of the deep trenches in the trench electrode pickup area.

11. The method of claim 8, wherein forming the at least one substrate electrode comprises:
forming first trenches at the deep trench isolations exposed at the second side of the semiconductor substrate, wherein the trench electrodes and the substrate cells around the trench electrodes are exposed in the first trenches;
forming a second isolation dielectric over the second side, which fills the first trenches and covers surfaces of the substrate cells;
forming second trenches, the bottom of which is located around the top of the first trenches, wherein the substrate cells around the deep trench isolations are exposed at side surfaces of the second trenches, and the trench electrodes are covered by the second isolation dielectric; and
filling a conductive material in the second trenches, forming the at least one substrate electrode.

12. The vertically charge transferring pixel sensor of claim 4, further comprising a gate dielectric layer formed on a surface of the semiconductor substrate, wherein in the pixel area, the at least one trench electrode underlies a lower surface of the gate dielectric layer and is covered by the deep-trench filling layer.

13. The vertically charge transferring pixel sensor of claim 6, wherein the second isolation dielectric has a dielectric constant greater than 3.9.

14. The vertically charge transferring pixel sensor of claim 5, wherein the second isolation dielectric further covers end faces of the semiconductor substrate at the second side.

15. The method of claim 9, further comprising forming a gate dielectric layer formed on a surface of the semiconductor substrate, wherein in the pixel area, the at least one trench electrode underlies a lower surface of the gate dielectric layer and is covered by the deep-trench filling layer.

16. The method of claim 11, wherein the second isolation dielectric comprises a high dielectric constant material.

17. The method of claim 16, wherein the second isolation dielectric has a dielectric constant greater than 3.9.

18. The method of claim 11, wherein the second isolation dielectric further covers end faces of the semiconductor substrate at the second side.
